(19) United States
(12) Patent Application Publication
(10) Pub. No.: US 2025/0212549 A1
(43) Pub. Date: Jun. 26, 2025

(54) PHOTOELECTRIC CONVERSION ELEMENT AND PHOTOELECTRIC CONVERSION DEVICE

(71) Applicant: TOHOKU UNIVERSITY, Sendai-shi, Miyagi (JP)

(72) Inventors: Toshiaki KATO, Sendai-shi (JP); Xing HE, Sendai-shi (JP); Toshiro KANEKO, Sendai-shi (JP)

(21) Appl. No.: 18/851,916

(22) PCT Filed: Mar. 23, 2023
(86) PCT No.: PCT/JP2023/011533

§ 371 Date: Sep. 27, 2024

(30) Foreign Application Priority Data
Mar. 30, 2022 (JP) 2022-055704

(51) Int. Cl. H10F 77/12; H10F 39/90; H10F 77/14; H10F 77/20

(52) U.S. Cl. CPC H10F 77/127; H10F 39/90; H10F 77/147; H10F 77/247

(57) ABSTRACT

Provided are a photoelectric conversion element and a photoelectric conversion device that are thin, have high conversion efficiency, and allow device scale-up. The photoelectric conversion element includes a photoelectric conversion member containing a transition metal dichalcogenide, and a first electrode and a second electrode that are connected to the photoelectric conversion member, in which the first electrode and the second electrode include facing portions where at least a part of the first electrode and at least a part of the second electrode are arranged to face each other in a parallel manner, and a length W of each of the facing portions and a separation distance Lch between the first electrode and the second electrode at the facing portions satisfy a relationship of W/Lch≤36.7. The photoelectric conversion device includes the photoelectric conversion element.

### CROSS-REFERENCE TO RELATED APPLICATIONS

This application is the U.S. National Stage entry of International Application No. PCT/JP2023/011533, filed on Mar. 23, 2023, which, in turn, claims priority to Japanese Patent Application No. 2022-055704, filed on Mar. 30, 2022, both of which are hereby incorporated herein by reference in their entireties for all purposes.

### TECHNICAL FIELD

The present invention relates to a photoelectric conversion element and a photoelectric conversion device used for a solar cell or the like.

### BACKGROUND ART

A transition metal dichalcogenide (TMD) is a material including a transition metal layer and a chalcogen atom layer and with each layer having a nano-sized thickness of 1 nm or less. The transition metal dichalcogenide has a structure of a nano-sized layer similar to that of graphene, but is different from graphene in that the transition metal dichalcogenide has a band gap due to an atomic structure. Since the transition metal dichalcogenide such electronic characteristics, it is expected to use the transition metal dichalcogenide as a material of a semiconductor.

The present inventors disclose a method for synthesizing a transition metal dichalcogenide in PTL 1. This technique provides a TMD synthesizing method capable of synthesizing a single crystal TMD or a heterojunction TMD by controlling a position of the single crystal TMD or the heterojunction TMD, so that the TMD can be advantageously synthesized when the TMD is applied to various devices.

The present inventors disclose a Schottky device for photoelectric conversion using a TMD as an application of the TMD in PTL 2. This technique provides a Schottky device that includes a transition metal dichalcogenide, and a first electrode and a second electrode that are joined to the transition metal dichalcogenide and in which a difference in work function between the first electrode and the second electrode is 0.4 eV or more. This technique provides a Schottky device having high conversion efficiency.

Since the TMD has a band gap for visible light, it is expected that it is suitable to use the TMD for various devices such as an optical device and an electronic device including, for example, a semiconductor element such as a diode or a transistor, a light emitting element, a light receiving element, and a photoelectric conversion element such as a solar cell. Further, since the TMD is a material having a nano-sized thickness, the TMD can have properties that are not available in an optical device or an electronic device made of a metal or a semiconductor material in the related art, such as light weight, flexibility, and transparency (light transmittance). Therefore, it is expected that the TMD can be applied to devices with a much wider application range as compared with an optical device or an electronic device in the related art.

For the purpose of applying such a TMD, the present inventors conducted studies and reported a method for producing a TMD in PTL 1 and a device using a TMD in PTL 2.

### CITATION LIST

### Patent Literature

PTL 1: JP6660203B

PTL 2: JP2017-147423A

### SUMMARY OF INVENTION

### Technical Problem

However, so far, a device using the TMD, including the device disclosed in PTL 2, was at a laboratory level in which a single element provided with an electrode is used for testing, and no technique has been reported at all for practical use, such as enlarging the device for a large capacity. Therefore, the present inventors conducted studies on scale-up of an element and a device known in the related art to commercialize a device using the TMD.

In addition, the present inventors newly found that a problem occurs when an element and a device known in the related art were used in scale-up of the element and the device, and conducted further studies to find a solution to this problem.

The invention has been made in view of the above circumstances, and an object of the invention is to provide a photoelectric conversion element and a photoelectric conversion device that are thin, have high conversion efficiency, and allow device scale-up.

### Solution to Problem

In order to solve the above problem, the invention has the following aspects.

According to a first aspect of the invention, provided is a photoelectric conversion element. The photoelectric conversion element includes a p photoelectric conversion member containing a transition metal dichalcogenide, and a first electrode and a second electrode that are connected to the photoelectric conversion member, in which the first electrode and the second electrode include respective facing portions where at least a part of the first electrode and at least a part of the second electrode are arranged to face each other in a parallel manner, and a length W of each of the facing portions and a separation distance L_{ch} between the first electrode and the second electrode at the facing portions satisfy a relationship of W/L_{ch}≤36.7.

According to a second aspect of the invention, in the photoelectric conversion element according to the first aspect, the length W is 500 nm or more and 500 μm or less, and the separation distance Len is 10 nm or more and 10 μm or less.

According to a third aspect of the invention, in the photoelectric conversion element according to the first or the second aspect, the photoelectric conversion member is transparent to visible light.

According to a fourth aspect of the invention, in the photoelectric conversion element according to any one of the first to third aspects, the first electrode and the second electrode are transparent to visible light.

According to a fifth aspect of the invention, in the photoelectric conversion element according to any one of the first to fourth aspects, the first electrode and the second electrode contain an indium tin oxide.

According to a sixth aspect of the invention, in the photoelectric conversion element according to any one of the first to fifth aspects, the photoelectric conversion member includes an antireflection agent layer on a surface of the photoelectric conversion member.

According to a seventh aspect of the invention, in the photoelectric conversion element according to any one of the first to sixth aspects, the photoelectric conversion member having a flat plate shape is provided on a base material having a flat plate shape via the first electrode and the second electrode.

According to an eighth aspect of the invention, provided is a photoelectric conversion device including a plurality the photoelectric conversion elements according to any one of the first to seventh aspects.

According to a ninth aspect of the invention, the photoelectric conversion elements are arranged such that an area of a planar portion, which is a sum of areas represented by W×L_{ch} of the lengths W and the separation distances L_{ch} of the photoelectric conversion members provided in the photoelectric conversion device according to the eighth aspect, is 0.1 cm² or more.

According to a tenth aspect of the invention, in the photoelectric conversion device according to the eighth aspect, at least two of the photoelectric conversion elements are connected in parallel and in series via the first electrode and the second electrode.

### Advantageous Effects of Invention

According to the invention, it is possible to provide a photoelectric conversion element and a photoelectric conversion device that are thin, have high conversion efficiency, and allow scale-up.

### BRIEF DESCRIPTION OF DRAWINGS

FIG. 1 is a schematic plan view showing a photoelectric conversion element 1 according to the present embodiment.

FIG. 2 is a cross-sectional view taken along a line A-A in FIG. 1.

FIG. 3 is a schematic plan view showing a photoelectric conversion device in which photoelectric conversion elements are connected in parallel.

FIG. 4 is a schematic plan view showing a photoelectric conversion device in which photoelectric conversion elements are connected in series.

FIG. 5 is a schematic plan view showing a photoelectric conversion device in which photoelectric conversion elements are connected in parallel and in series.

FIG. 6 is a schematic view showing a test element according to the present embodiment.

FIG. 7 is a graph showing photoelectric conversion performance of the test element according to the present embodiment.

FIG. 8 is a schematic view showing a photoelectric conversion device according to the present embodiment and a graph showing photoelectric conversion performance.

FIG. 9 shows an image of the photoelectric conversion device according to the present embodiment, a graph showing photoelectric conversion performance, and a graph showing transparency.

### DESCRIPTION OF EMBODIMENTS

Hereinafter, an embodiment of a photoelectric conversion element and a photoelectric conversion device according to the invention will be described. However, the invention is not limited to the following embodiment.

### Photoelectric Conversion Element

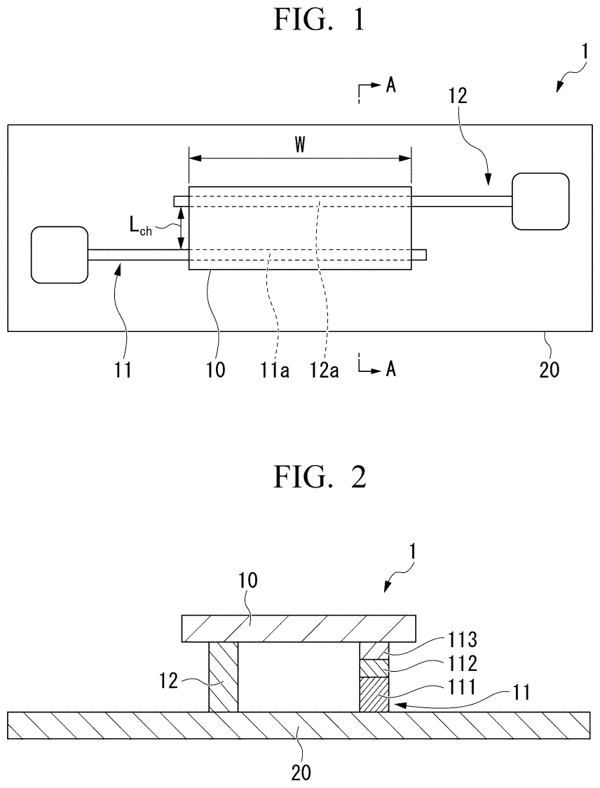

FIG. 1 is a schematic plan view showing a photoelectric conversion element 1 according to the present embodiment, and FIG. 2 is a cross-sectional view taken along a line A-A in FIG. 1. As shown in the drawings, the photoelectric conversion element 1 includes at least a photoelectric conversion member 10, and a first electrode 11 and a second electrode 12 that are connected to the photoelectric conversion member 10. In the present embodiment, the photoelectric conversion element 1 further includes a base material 20.

### Photoelectric Conversion Member

The photoelectric conversion member 10 is made of a constituent material containing a transition metal dichalcogenide (TMD). The TMD contained in the constituent material of the photoelectric conversion member 10 is a compound represented by a general formula MCh2. Here, M is a transition metal element, and specifically, is Ti, Zr, Hf, V, Nb, Ta, Mo, W, or the like. Ch2 represents chalcogenide, and specifically, is S, Se, Te, or the like. The TMD has a structure in which a monomolecular layer of a transition metal element M is interposed between monomolecular layers made of chalcogen atoms. Hereinafter, one unit of Ch2 is referred to as one TMD layer. The number of layers of the TMD used as a constituent material of the photoelectric conversion member 10 is preferably 6 or less, and more preferably 3 or less. It is preferable that the number of layers of the TMD is 6 or less because transparency to visible light to be described below can be increased.

As the TMD, either a single crystal or a polycrystal may be used, but it is preferable to use a single crystal because electrical conductivity and optical characteristics of the photoelectric conversion element 1 can be improved. For example, PTL 1 discloses a method for obtaining a single crystal TMD.

The photoelectric conversion member 10 is preferably transparent to visible light. In the present embodiment, visible light refers to light in a wavelength band of 360 nm or more and 830 nm or less. The expression “transparent to visible light” refers to that an average transmittance of visible light measured by a spectrophotometer is 70% or more, and more preferably 80% or more.

Since the photoelectric conversion member 10 is transparent to visible light, the photoelectric conversion element 1 can be disposed on a transparent member. For example, when an area of a solar cell or the like is large, the photoelectric conversion element 1 can be disposed in a transparent structure such as a window of a building or a wall of a vinyl house to obtain a large capacity. It is also possible to dispose the photoelectric conversion element 1 in an inconspicuous member or a member that does not impair a surrounding view. Because these effects, the photoelectric conversion element 1 having an extremely wide application range can be obtained.

On the other hand, the photoelectric conversion member 10 can be used even when the photoelectric conversion member 10 is not transparent to visible light.

The photoelectric conversion member 10 preferably includes an antireflection agent layer on a surface of the photoelectric conversion member 10. A material known in the related art that has an effect of preventing reflection of visible light can be appropriately used as a material of the antireflection agent layer. The antireflection agent layer may be formed by using an antireflection film or the like, or may be formed by directly coating with an antireflection agent having an antireflection effect. In order to maintain effects of the photoelectric conversion member 10, such as light weight, flexibility, and transparency, it is preferable to use a layer directly coated with an antireflection agent and having a small thickness.

Examples of the antireflection agent include an agent containing a fluoride compound or the like, and specifically, include magnesium fluoride, aluminum fluoride, calcium fluoride, lithium fluoride, sodium fluoride, fluororesin, and fluoride nanoparticle, or WO₃, MoO₃, TiO₂, or the like.

Since the photoelectric conversion member 10 includes the antireflection agent, when the photoelectric conversion member 10 is transparent to visible light, refraction and reflection of light occurred between the photoelectric conversion member 10 and another member can be prevented, and the transparency of the photoelectric conversion member 10 to visible light can be enhanced.

The photoelectric conversion member 10 may have any shape and size, but preferably has a small thickness in order to increase transparency, light weight, and flexibility to be described later. Although the thickness is 0.8 nm to 10 nm as a standard, a sufficiently small thickness can be obtained by setting the total number of layers of the TMD to 6 or less as described above.

The photoelectric conversion member 10 may have any size, but for example, when the photoelectric conversion member 10 includes one first electrode 11 and one second electrode 12 as shown in FIG. 1, it is preferable to appropriately select the size that allows each electrode to be provided based on values of W and L_{ch} to be described later.

In the present embodiment, the photoelectric conversion member 10 is formed in a form of a rectangular flat plate having a diameter sufficient to ensure thickness of one TMD layer and a length and a distance related to the electrodes as will be described later.

The photoelectric conversion element 1 includes at least the first electrode 11 and the second electrode 12 that are connected to the photoelectric conversion member 10. In the present embodiment, as shown in the drawing, the first electrode 11 and the second electrode 12 are both linear, are disposed apart from each other, and are provided in close contact with the photoelectric conversion member 10.

### First and Second Electrodes

A constituent material of the first and the second electrodes 11 and 12 can be appropriately selected from materials having electrical conductivity. Examples of the constituent material of the first and second electrodes 11 and 12 include an inorganic conductive layer containing an inorganic conductive material, an organic conductive layer containing an organic conductive material, and an organic-inorganic conductive layer containing both an inorganic conductive material and an organic conductive material. For example, a metal or a metal oxide may be used as the inorganic conductive material. Here, the metal is defined as including semi-metal. For example, a carbon material or a conductive polymer can be used as the organic conductive material.

The first and second electrodes 11 and 12 may be thin films obtained by a physical vapor deposition (PVD) method or a chemical vapor deposition (CVD) method, or may be thin films obtained by a coating method such as a printing method. As will be described later, the first and second electrodes 11 and 12 may be formed by electron beam (EB) lithography, photolithography, sputtering, or the like.

It is preferable that the first electrode 11 and the second electrode 12 are selected such that a difference in work function between the first electrode 11 and the second electrode 12 is equal to or larger than a certain value. Specifically, the difference in work function between the first electrode 11 and the second electrode 12 is preferably 0.4 eV or more, more preferably 0.48 eV or more, and still more preferably 0.56 eV or more. When the difference in work function is the above values or more, photoelectric conversion efficiency is increased. In the present embodiment, for the sake of convenience, the first electrode 11 is one electrode having a large work function value, and the second electrode 12 is the other electrode having a small work function value.

Furthermore, it is preferable that one of the first electrode 11 and the second electrode 12 having a large work function has a larger work function than the TMD, and the other one having a small work function has a smaller work function than the TMD.

The first electrode 11 and the second electrode 12 are preferably transparent to visible light. Since the first electrode 11 and the second electrode 12 are transparent to visible light, when the first electrode 11 and the second electrode 12 are provided in the photoelectric conversion element 1, transparency of the photoelectric conversion member 10 is not hindered, and therefore, the entire photoelectric conversion element 1 are transparent to visible light as will be described later. In addition, since the first electrode 11 and the second electrode 12 are transparent to visible light, light is transmitted through the electrodes, and therefore conversion efficiency of the photoelectric conversion member 10 can be increased.

It is preferable that the entire photoelectric conversion element 1 including the photoelectric conversion member 10, the first electrode 11, and the second electrode 12 is transparent to visible light. Since the photoelectric conversion element 1 has transparency, the photoelectric conversion element 1 can be installed in a portion or a member that requires transparency, and therefore an application range of the photoelectric conversion element 1 can be widened.

It is preferable that the first electrode 11 and the second electrode 12 are made of a constituent material containing an indium tin oxide (ITO). Since the indium tin oxide has electrical conductivity and high transparency, the first electrode 11 and the second electrode 12 can be configured to be transparent to visible light.

An electrode containing an indium tin oxide can be formed by, for example, forming a pattern on a target surface on which the electrode is to be formed by electron beam (EB) lithography, photolithography, sputtering, or the like.

In the present embodiment, as shown in FIG. 2, the first electrode 11 is an electrode containing ITO, Cu, and WO₃. In the first electrode 11, an ITO layer 111 which is a film of indium tin oxide, a Cu layer 112 which is a film of copper having a thickness of about 1 nm, and a WO₃ layer 113 which is a film of tungsten trioxide having a thickness of about 1 nm are sequentially formed on the base material 20 by EB lithography. The second electrode 12 is an electrode containing ITO and includes only an ITO layer which is a film of indium tin oxide, and is formed on the photoelectric conversion member 10 by EB lithography. The photoelectric conversion member 10 is provided in a manner of being in contact with the first electrode 11 and the second electrode 12 with the first electrode 11 and the second electrode 12 interposed therebetween.

In the present embodiment, each of the electrodes and a thicknesses of a film constituting each of the electrodes can be appropriately selected, and a thicknesses of each of the Cu layer 112 and the WO3 layer 113 is preferably 5 nm or less.

### Facing Portion and Separation Distance between Electrodes

As shown in FIG. 1, in the photoelectric conversion element 1, the first electrode 11 and the second electrode 12 have facing portions 11a and 12a where at least a part of the first electrode 11 and a part of the second electrode 12 are arranged to face each other in a parallel manner. In addition, a length W of each of the facing portions 11a and 12a and a separation distance Lon between the first electrode 11 and the second electrode 12 at the facing portions 11a and 12a satisfy a relationship of W/L_{ch}≤36.7.

In an example shown in the drawing, the first electrode 11 having a rectangular shape has the facing portion 11a, and the second electrode 12 has the facing portion 12a. The facing portions 11a and 12a face each other in parallel. Here, the term “parallel” includes substantially parallel, that is, parallel including a range of error. In particular, the facing portions 11a and 12a are provided at portions in contact with the photoelectric conversion member 10. In the drawing, a length (a long side width) of each of the facing portions 11a and 12a is indicated by W. The facing portions 11a and 12a are separated by a separation distance L_{ch} (a channel length).

The length W and the separation distance L_{ch} satisfy a relationship of W/L_{ch}≤36.7. The length W and the separation distance L_{ch} more preferably satisfy a relationship of 0.001≤W/L_{ch}≤30, and further preferably satisfy a relationship of 1.0≤W/L_{ch}≤10.

A ratio of the length W to the separation distance L_{ch} may be represented by R=W/L_{ch}.

When the length W and the separation distance L_{ch} satisfy the above relationships, photoelectric conversion efficiency, that is, performance when used for power generation or the like does not decrease. Therefore, W or L_{ch} can be set as long as the above relationships are satisfied, and the photoelectric conversion element 1 can be set to various sizes and scales including scale-up.

The present inventors attempted to scale up a photoelectric conversion element using the TMD, which was not attempted so far. If the photoelectric conversion performance does not decrease even when the size of the photoelectric conversion element using the TMD is increased, it is possible to obtain a photoelectric conversion element having a thin property because the TMD at an atomic layer level is used and having properties of transparency, light weight, and flexibility and photoelectric conversion performance at the same time.

However, as a result of the above attempt, the present inventors found that there was a previously unknown problem in scaling up the photoelectric conversion element using the TMD according to a technique in the related art.

That is, the present inventors found that, in a photoelectric conversion element including an electrode and a photoelectric conversion member, when the electrode and the photoelectric conversion member were increased in size, and, for example, the length W of the electrode was increased, photoelectric conversion performance decreased if the length W exceeded a certain length.

Therefore, the present inventors conducted extensive research into conditions of the photoelectric conversion element, such as a size of each element, and as a result, the present inventors found that there was a clear threshold for the ratio R=W/L_{ch} of the length W and the separation distance L_{ch}, which allows the photoelectric conversion performance to be maintained, and that a photoelectric conversion element in which the performance did not decrease could be obtained by setting R=W/L_{ch} to be equal to or lower than the threshold.

W is preferably 500 nm or more and 500 μm or less, and L_{ch} is preferably 10 nm or more and 10 μm or less. A range of the length W and the separation distance Ich are values selected according to scales of the facing portions 11a and 12a, that is, a scale of the photoelectric conversion element. When W and L_{ch} are smaller than the above values, that is, when the scale of the photoelectric conversion element is too small, processing becomes difficult, and a large number of photoelectric conversion elements are required for scale-up, which may be inefficient. When W and L_{ch} are larger than the above values, that is, when the scale of the photoelectric conversion element is too large, a configuration of a device or an apparatus in which the photoelectric conversion elements are combined may be limited.

L_{ch} is preferably 1 μm or more and 5 μm or less, more preferably 2 μm or more and 4 μm or less, and particularly preferably about 2 μm. When L_{ch} is 1 μm or more, a short channel effect (SCE) is less likely to occur, and conversion efficiency is less likely to decrease. When L_{ch} is 5 μm or less, conversion efficiency is less likely to decrease due to carrier loss.

In the photoelectric conversion element 1, it is also preferable that the photoelectric conversion member 10 having a flat plate shape is provided on the base material 20 having a flat plate shape via the first electrode 11 and the second electrode 12.

The base material 20 is provided for holding and protecting other members. As in the present embodiment, an electrode structure or the like may serve as a base material formed by sputtering, lithography, or the like.

The base material 20 is preferably an insulator.

When the photoelectric conversion member 10 0 is transparent to visible light, the base material is also preferably transparent to visible light. A shape of the base material 20 can be selected from, for example, a film shape, a plate shape, and a block shape, but is not limited thereto. The base material 20 may have flexibility or may not have flexibility (have rigidity).

A material of the base material 20 can be appropriately selected from various resins, inorganic materials, and the like. As the resin, a polymeric resin such as various plastics can be used. As the inorganic material, various types of glass, quartz crystal, and the like can be used. In the present embodiment, the base material 20 is made of quartz crystal. A size of the base material 20 can be appropriately selected such that other members of the photoelectric conversion element 1 can be held and transparency is not impaired if necessary.

### Photoelectric Conversion Device

A photoelectric conversion device according to the present embodiment includes a plurality of the above-described photoelectric conversion elements 1.

Specifically, the photoelectric conversion elements 1 are connected in parallel or in series.

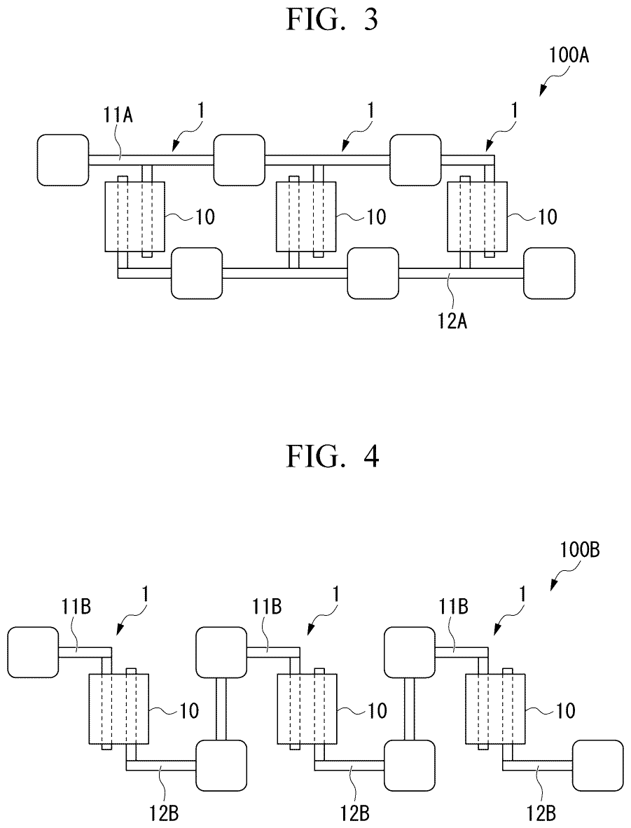

FIG. 3 is a schematic plan view showing a photoelectric conversion device 100A in which the photoelectric conversion elements 1 are connected in parallel. In an example shown in the drawing, although three photoelectric conversion elements 1 are connected in parallel, the number of the connected photoelectric conversion elements may be two or more. A first electrode 11A extends so as to connect first electrodes of the photoelectric conversion elements 1. A second electrode 12A extends so as to connect second electrodes of the photoelectric conversion elements 1. Other configurations of the first electrode 11A and the second electrode 12A are the same as those described above.

The base material 20 is omitted in the drawing. In the example shown in the drawing, the base material 20 may be a base material having an area at which all of the plurality of photoelectric conversion elements 1 are provided on the base material 20.

FIG. 4 is a schematic plan view showing a photoelectric which the conversion device 100B in photoelectric conversion elements 1 are connected in series. In an example shown in the drawing, although three photoelectric conversion elements 1 are connected in series, the number of the connected photoelectric conversion elements may be two or more. A first electrode 11B extends so as to be connected to a second electrode 12B of another photoelectric conversion element 1. The second electrode 12B extends so as to be connected to the first electrode 11B of another photoelectric conversion element 1. Other configurations of the first electrode 11B and the second electrode 12B are the same as those described above.

The base material 20 is omitted in the drawing. In the example shown in the drawing, the base material 20 may be a base material having an area at which the entire photoelectric conversion device 100B, that is, all of the plurality of photoelectric conversion elements 1 are provided on the base material 20.

In the photoelectric conversion device according to the present embodiment, the photoelectric conversion elements may be connected in parallel and in series. By appropriately combining parallel connection and series connection, a current loss is less likely to occur. As a guideline, for the series connection, it is preferable to connect two to ten photoelectric conversion elements in series, and more preferable two to five photoelectric conversion elements. For the parallel connection, it is preferable to connect two or more and 50 or less photoelectric conversion elements in parallel, and more preferable two or more and ten or less photoelectric conversion elements.

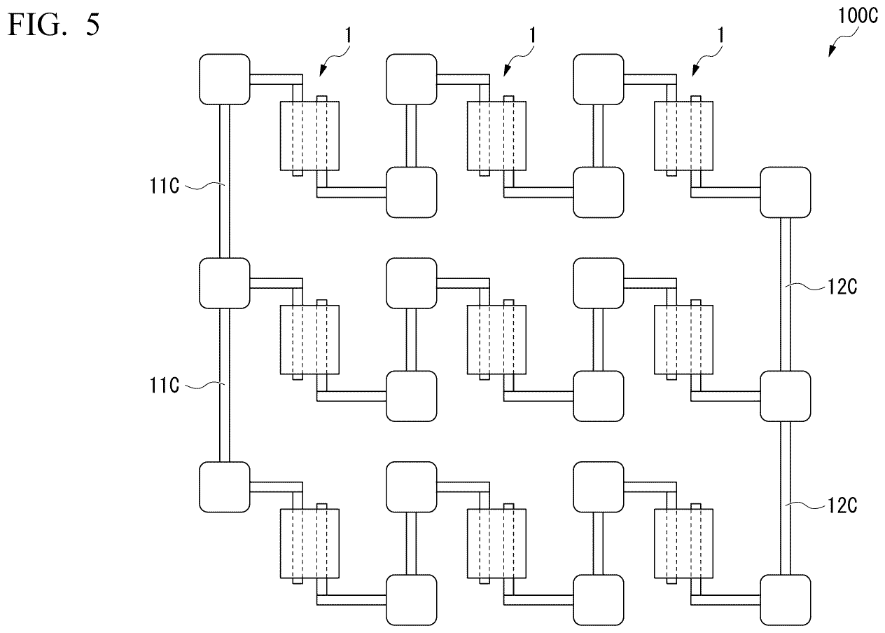

FIG. 5 shows a photoelectric conversion device 100C in which at least two rows of the photoelectric conversion elements 1 are connected in parallel and in series via the first electrode and the second electrode. The photoelectric conversion device 100C has a configuration in which the photoelectric conversion elements 1 are connected in series in three rows (a left-right direction in the drawing) via electrode extension portions 11C and 12C made of the same constituent material as the first electrode 11 and the second electrode 12, respectively, and are further connected in parallel in three rows (an up-down direction in the drawing).

In another embodiment, connection between the photoelectric conversion elements 1 may be made by connecting the first electrodes or the second electrodes via another member having conductivity. The base material 20 may be provided for each photoelectric conversion element 1, or may be provided in a manner in which a plurality of the photoelectric conversion elements 1 are provided on the base material 20.

An effect of the photoelectric conversion device according to the present embodiment is that since a plurality of the above-described photoelectric conversion elements are provided, the photoelectric conversion device can be scaled up while maintaining photoelectric conversion efficiency without changing a scale of the photoelectric conversion element, that is, while maintaining a configuration in which R=W/L_{ch} is equal to or less than a threshold.

The photoelectric conversion device is preferably arranged such that an area of a planar portion is 0.1 cm² or more. In the photoelectric conversion device according to the present embodiment, the area of the planar portion is an area of a plane perpendicular to an incident direction of light on the photoelectric conversion member 10. More specifically, the area of the planar portion is an area represented by W×L_{ch} in FIG. 1. When the photoelectric device includes a plurality of photoelectric conversion members 10 (or a plurality of photoelectric conversion elements 1 including the photoelectric conversion members 10), the area of the planar portion is a sum of areas represented by W×L_{ch} of the lengths W and the separation distances Lon of the plurality of photoelectric conversion members provided in the photoelectric conversion device. It is more preferable that the photoelectric conversion device is arranged such that the area of the planar portion is 1.0 cm² or more.

As described above, a photoelectric conversion element in the related art has a problem that photoelectric conversion efficiency decreases when a scale is changed. In the photoelectric conversion device according to the present embodiment, the planar portion can be made to have an area of 0.1 cm² or more, and the photoelectric conversion device can be used in a practical scale when it is used for power generation or the like.

### Other Embodiments

The photoelectric conversion element according to the present embodiment can also be used in a method for manufacturing the photoelectric conversion device. That is, the photoelectric conversion element can also be used in the method for manufacturing the photoelectric conversion device including a step of connecting the above-described photoelectric conversion elements.

The photoelectric conversion device or the method for manufacturing the photoelectric conversion device can also be used for an apparatus including the photoelectric conversion device or a method for manufacturing the apparatus. Examples of such an apparatus include an apparatus including a solar cell.

### Purpose of Use of Photoelectric Conversion Element and Photoelectric Conversion to Present Device According Embodiment

The photoelectric conversion element and the photoelectric conversion device according to the present embodiment can be suitably used for various devices such as an optical device and an electronic device including, for example, a semiconductor element such as a diode and a transistor, a light emitting element, a light receiving element, and a photoelectric conversion element such as a solar cell. In particular, the photoelectric conversion element and the photoelectric conversion device according to the present embodiment can be scaled up while maintaining photoelectric conversion performance, and have properties such as transparency, plasticity, and light weight, and thus it is preferable to apply the photoelectric conversion element and the photoelectric conversion device according to the present embodiment to an apparatus such as a solar cell and various sensors in consideration of a variety of use and providing locations and use conditions.

### Effects of Photoelectric Conversion Element and Conversion Device According to Present Photoelectric Embodiment

In the related art, in order to manufacture a transparent photoelectric conversion element for use in a solar cell or the like, an attempt was made to use a highly transparent material such as a fluorine-doped tin oxide (ITO). However, since ITO cannot perform photoelectric conversion by ITO alone, it is necessary to mix ITO with another element or compound, or coat another element or compound on a surface of ITO, or add another member to ITO. Therefore, light weight, flexibility, and transparency are impaired, and the object of the invention cannot be achieved.

A photoelectric conversion element using a constituent material containing a transition metal dichalcogenide (TMD) has a configuration called an atomic layer material which is a two-dimensional sheet having a thickness on an atomic order. Since the atomic layer material can generate power, it is not necessary to use other members or coating materials, and in principle, it is possible to increase an area. However, there is no previous example for increasing an area of the photoelectric conversion element while maintaining light weight, flexibility, or transparency.

The present inventors attempted to increase the area of the photoelectric conversion element using a constituent material containing TMD, and found a phenomenon in which power generation performance decreased when the area was further increased. As a solution to this problem, the present inventors found a constituent condition of the photoelectric conversion element without characteristic deterioration, and achieved a photoelectric conversion element and a photoelectric conversion device that achieved a maximum power generation amount when the photoelectric conversion element and the photoelectric conversion device were used in an atomic layer solar cell. As a result, a photoelectric conversion element and a photoelectric conversion device such as a solar cell using an atomic layer material and having transparency exceeding 79% in terms of visible light transmittance, light weight, and flexibility were achieved.

A device, thin, has light weight, which is flexibility, transparency, and the like, has high photoelectric conversion efficiency, and can be scaled up, can be matched with various environments and living spaces, and high practicability can be expected.

Although the embodiment of the invention has been described above, the invention is not limited to the above embodiment, and various modifications can be made.

### EXAMPLES

Effects of the invention will be more clearly understood based on the following examples. It should be noted that the invention is not limited to the following examples, and can be appropriately modified without departing from the scope of the invention.

### Test Example 1

### Study about Condition for Configuration of Photoelectric Conversion Element

The present inventors found that photoelectric conversion efficiency decreased when a photoelectric conversion element in the related art as disclosed in PTL 2 or the like was used and was simply scaled up to a millimeter order. Specifically, even when a photoelectric conversion element was produced by scaling up a nano-sized electrode and a photoelectric conversion member with W having a length on the order of micrometers or millimeters, a result was obtained in which obtained power did not increase in proportion to a size (not shown).

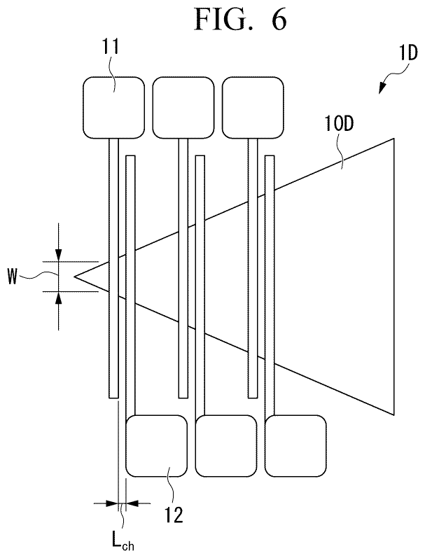

In order to study a condition for a configuration of the photoelectric conversion element, a test element 1D shown in FIG. 6 was prepared.

The test element 1D includes a photoelectric conversion member 10D, and a plurality of first electrodes 11, and a plurality of second electrodes 12. The photoelectric conversion member 10D including a single TMD film and having a triangular shape with a thickness of 0.8 nm and a bottom side and a height of about 500 μm was prepared. The first electrode 11 and the second electrode 12 each having a length of about 500 μm were provided on the quartz crystal base material 20 (not shown) in a manner in which a separation distance between the first electrode 11 and the second electrode 12 was L_{ch} as will be described later. The first electrode 11 was an ITO/Cu/WO₃ electrode, and an ITO layer which is an indium tin oxide film, a Cu layer which is a copper film having a thickness of about 1 nm, and a WO₃ layer 113 which is a tungsten trioxide film having a thickness of about 1 nm were sequentially formed on the base material 20 by EB lithography. The second electrode 12 was an ITO electrode, and an ITO layer which is an indium tin oxide film was formed by EB lithography.

The photoelectric conversion member 10D was provided on the base material 20 in a manner of being in contact with the first electrode 11 and the second electrode 12 with the first electrode 11 and the second electrode 12 being interposed between the photoelectric conversion member 10D and the base material 20. That is, since a contact length between the photoelectric conversion member 10D and each of the first electrode 11 and the second electrode 12 is increased in order from the vicinity of an apex of the triangular shape of the photoelectric conversion member 10D to the vicinity of a bottom, lengths W of each of the facing portions 11a and 12a where the first electrode 11 and the second electrode 12 face each other and are in contact with the photoelectric conversion member 10D are sequentially obtained from a short structure to a long structure.

With this structure, test elements 1D in which L_{ch}=1 μm to 4 μm were prepared by changing a separation distance between the electrodes. By examining photoelectric conversion performance of each element, a relationship between the length W of the facing portions of the electrodes and the separation distance L_{ch} between the electrodes was examined by changing the length W and the distance L_{ch}.

The test element 1D was irradiated with light (a 300 W xenon lamp, AM 1.5G) from a pseudo solar light source HAL-320 (Asahi Spectra Co., Ltd.), and photoelectric conversion performance between the first electrode and the second electrode was examined by a semiconductor parameter analyzer HP 4155C (Agilent Technologies, Inc.). Standard solar cell AK-100 (Konica Minolta Japan, Inc.) was used for correction.

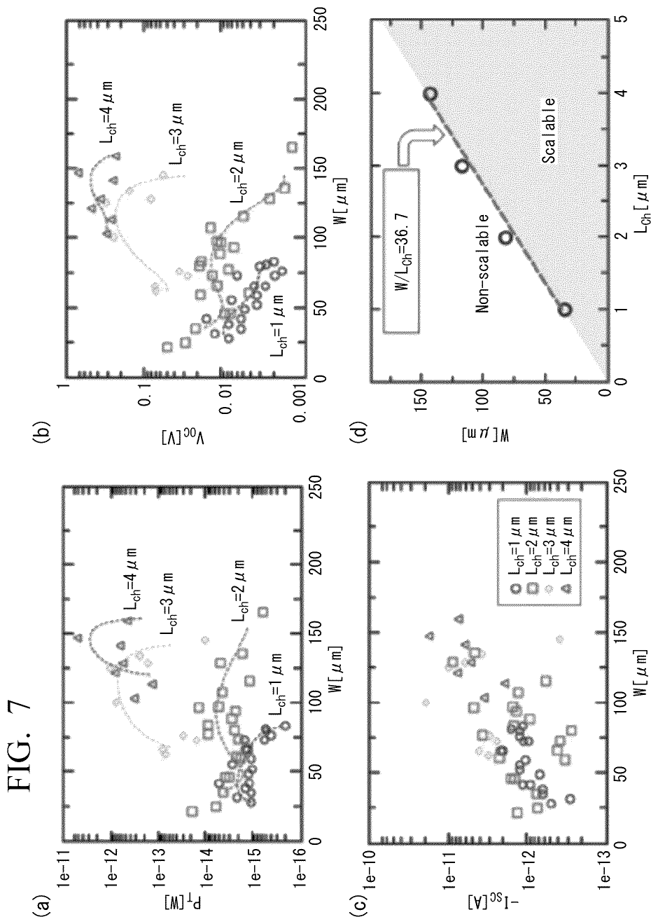

When the separation distance L_{ch}=1 μm to 4 μm and a horizontal axis was set as the length W, (a) of FIG. 7 shows power PT between the first electrode and the second electrode, (b) of FIG. 7 shows a voltage V_{OC}, and (c) of FIG. 7 shows a current I_{SC}.

In the drawing, a graph shows a mountain-like curve, that is, when W exceeds a certain value (a critical value) for each L_{ch}, power, voltage, or current generated by photoelectric conversion decreases. Specifically,
at L_{ch}=1 μm, when W exceeded 33.5 μm,
at L_{ch}=2 μm, when W exceeded 81.3 μm,
at L_{ch}=3 μm, when W exceeded 116.3 μm, and
at L_{ch}=4 μm, when W exceeded 142 μm,
results showed that the power P_{T} and the voltage V_{OC} decreased.

(d) of FIG. 7 shows a graph obtained by plotting critical values of W for each L_{ch}. The graph is substantially a straight line, and calculations from the graph show that when W/L_{ch} exceeds a value of 36.7, photoelectric conversion performance decreases. That is, the graph showed that W/L_{ch}≤36.7 was a threshold at which the photoelectric conversion performance does not decrease.

### Test Example 2

### Performance Comparison of Photoelectric Conversion Device

When a photoelectric conversion device was produced using the photoelectric conversion element according to the present embodiment, it was examined whether the photoelectric conversion device could be increased in size or whether performance did not decrease as compared with the case of using an element in the related art.

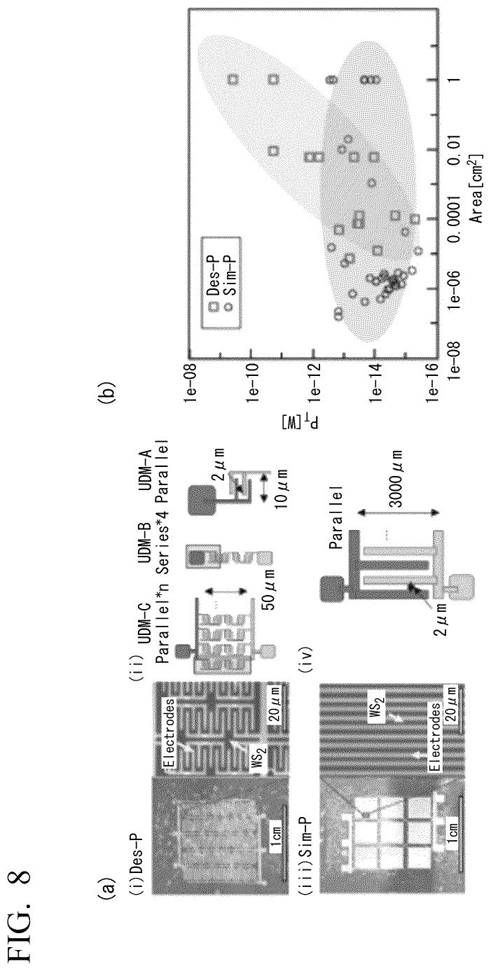

As shown in (a) of FIG. 8, an example (Des-P) of a photoelectric conversion device including the photoelectric conversion element according to the present embodiment and a comparative example (Sim-P) in which the element in the related art was increased in size were produced.

For Des-P, as shown in (ii) of (a), a photoelectric conversion element was produced using a first electrode, a second electrode, and a TMD similar to those in Test Example 1 with L_{ch}=2 μm and W=10 μm (W/L_{ch}=5.0), and four photoelectric conversion elements were connected in series. A size of a long side of the series was 50 μm. Four elements connected in series were connected in parallel.

For each area where the elements were connected, power of photoelectric conversion was measured by a measurement method the same as that in Test Example 1. A maximum area was measured for a photoelectric conversion device having a size of 1 cm×1 cm as shown in (i) of (a).

For Sim-P, as shown in (iv) of (a), an element was produced using a first electrode, a second electrode, and TMD similar to those in Test Example 1 with L_{ch}=2 μm and W=3000 μm (W/L_{ch}=1500). The first electrode and the second electrode are each formed in a comb shape and arranged in parallel to have a maximum width of 3000 μm.

For each area where the elements were connected, power of photoelectric conversion was measured by a measurement method the same as that in Test Example 1. A maximum area was measured for a photoelectric conversion device having a size of about 1 cm×1 cm by connecting the elements (3 mm×3 mm) in parallel in 3×3 as shown in (iii) of (a).

(b) of FIG. 8 shows values of the power P_{T} for each area in the example (Des-P) and the comparative example (Sim-P). In the Des-P, when the photoelectric conversion elements are connected to increase an area, power generated by photoelectric conversion is increased substantially in proportion to the area. On the other hand, in the Sim-P, a size of the area is not proportional to the power. That is, in the case of an element in which W/L_{ch}≤36.7 is not satisfied in the comparative example, power cannot be increased even when the elements are connected to each other to increase a size.

It was found that, in the photoelectric conversion element according to the present example, when a size of the photoelectric conversion device was increased, generated power was increased in proportion to the size, and the photoelectric conversion device could be scaled up.

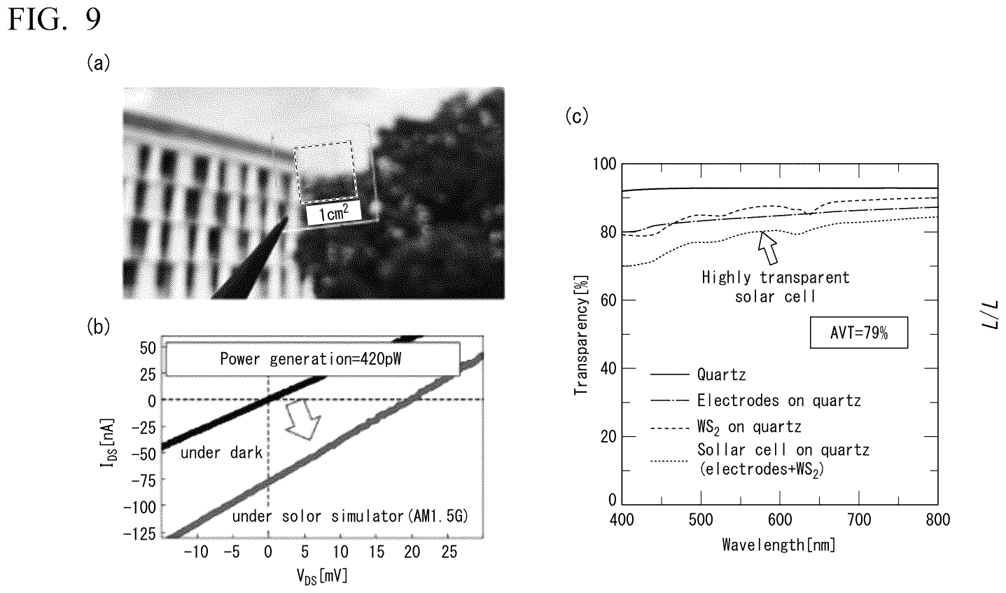

(a) of FIG. 9 shows an image of the photoelectric conversion device according to the present example. The photoelectric conversion device according to the present example is almost visually transparent even when the device having one side of 1 cm or more is formed.

(b) of FIG. 9 shows results obtained by measuring current and voltage values of photoelectric conversion of the photoelectric conversion device according to the present example. In the measurement, the pseudo solar light source and the semiconductor parameter analyzer shown in Test Example 1 were used. As shown in the drawing, when the photoelectric conversion device according to the present example was used, power value was 420 pW.

(c) of FIG. 9 shows results obtained by measuring transparency (light transmittance) of the photoelectric conversion device according to the present example. The transparency, that is, average light transmittance (AVT) was obtained according to a calculation formula of AVT=∫T(λ)P(λ)S(λ)d(λ)/∫P(λ)S(λ)d(λ) (λ: wavelength, T: transmission, P: photopic response, S: solar photon flux) (set in AM 1.5G) by using a UV visible near infrared spectrophotometer V-7200HK (JASCO Corporation).

As shown in the drawing, the photoelectric conversion device according to the present example exhibited AVT=79% in a range of visible light, and a result of being almost transparent was obtained. The result showed that the photoelectric conversion device according to the present example was scaled up while maintaining performance and was transparent to visible light.

### INDUSTRIAL APPLICABILITY

The photoelectric conversion element and the photoelectric conversion device according to the invention are thin, have high conversion efficiency, and allow device scale-up.

### REFERENCE SIGNS LIST

1: photoelectric conversion element
1D: test element
10, 10D: photoelectric conversion member
11, 11A, 11B: first electrode
11C, 12C: electrode extension portion
11a, 12a: facing portion
12, 12A, 12B: second electrode
20: base material
100A, 100B, 100C: photoelectric conversion device
111: ITO layer
112: Cu layer
113: WO₃ layer
L_{ch}: separation distance
W: length

1. A photoelectric conversion element comprising:
a photoelectric conversion member containing a transition metal dichalcogenide; and
a first electrode and a second electrode connected to the photoelectric conversion member, wherein
the first electrode and the second electrode include facing portions where at least a part of the first electrode and at least a part of the second electrode is arranged to face each other in a parallel manner, and
a length W of each of the facing portions and a separation distance L_{ch} between the first electrode and the second electrode at the facing portions satisfy a relationship of W/L_{ch}≤36.7.

2. The photoelectric conversion element according to claim 1, wherein
the length W is 500 nm or more and 500 μm or less, and the separation distance L_{ch} is 10 nm or more and 10 μm or less.

3. The photoelectric conversion element according to claim 1, wherein
the photoelectric conversion member is transparent to visible light.

4. The photoelectric conversion element according to claim 1, wherein
the first electrode and the second electrode are transparent to visible light.

5. The photoelectric conversion element according to claim 1, wherein
the first electrode and the second electrode contain an indium tin oxide.

6. The photoelectric conversion element according to claim 1, wherein
the photoelectric conversion member includes an antireflection agent layer on a surface of the photoelectric conversion member.

7. The photoelectric conversion element according to claim 1, wherein
the photoelectric conversion member having a flat plate shape is provided on a base material having a flat plate shape via the first electrode and the second electrode.

8. A photoelectric conversion device comprising:
a plurality of the photoelectric conversion elements according to claim 1.

9. The photoelectric conversion device according to claim 8, wherein
the photoelectric conversion elements are arranged such that an area of a planar portion, which is a sum of areas represented by W×L_{ch} of the lengths W and the separation distances L_{ch} of the photoelectric conversion members provided in the photoelectric conversion device, is 0.1 cm² or more.

10. The photoelectric conversion device according to claim 8, wherein
at least two rows of the photoelectric conversion elements are connected in parallel and in series via the first electrode and the second electrode.
